(19) United States
(12) Patent Application Publication
(10) Pub. No.: US 2007/0075714 A1
(43) Pub. Date: Apr. 5, 2007

(54) Dual-chamber solution packaging system

(76) Inventors: Harli M. Dollinger, Fort Worth, TX (US); Kerry L. Markwardt, Burleson, TX (US); William E. McCune, Fort Worth, TX (US); Christian Masterson, Arlington, TX (US)

Correspondence Address: ALCON, IP LEGAL, TB4-8, 6201 SOUTH FREEWAY, FORT WORTH, TX, 76134, US

(21) Appl. No.: 11/529,184

(22) Filed: Sep. 28, 2006

Related U.S. Application Data
(60) Provisional application No. 60/721,871, filed on Sep. 29, 2005.

(51) Int. Cl. G01R 31/02

(52) U.S. Cl. 324/754

(57) ABSTRACT

A solution packaging system and method of administering a solution are disclosed. One embodiment of the solution packaging system of the present invention comprises a gas-impermeable dual-chamber bag, having a first chamber and a second chamber separated by a frangible (releasable) seal, and an over-wrap member enclosing and containing the dual-chamber inner bag. The dual-chamber bag can be used to package two-part medicinal solutions containing bicarbonate, such as ophthalmic irrigation solutions. The first chamber can be filled with and contain a first part of such an irrigation solution, comprising, for example, a buffer such as bicarbonate. The second chamber can contain the second part of such a solution, comprising, for example, glutathione (GSSG), or other anti-oxidant, and dextrose, or other energy source. Both parts may contain other excipients. The over-wrap member can serve as a dust cover and need not be a moisture or gas barrier, as the dual-chamber inner bag will have sufficient gas barrier properties to minimize the loss of CO₂ from the first part of the solution (e.g., the bicarbonate). All of the components of the dual-chamber solution packaging system can withstand steam sterilization. The dual-chamber bag can be fitted with an administration port, which can be manufactured of, for example, polypropylene (PP), and sealed with a stopper (e.g., butyl rubber stopper) and an aluminum crimp seal. The dual-chamber bag can further comprise fill-ports to fill each chamber. The fill port openings can be sealed after filling the chambers and the fill ports cut from the dual-chamber bag. The frangible seal between the chambers of the embodiments of this invention can be broken by the end user to mix and reconstitute the two parts of the solution prior to use.

### CROSS-REFERENCE TO RELATED APPLICATIONS

This application claims priority under 35 U.S.C. § 119 to U.S. Provisional Patent Application No. 60/721,871, filed Sep. 29, 2005, the entire contents of which are incorporated herein by reference.

### TECHNICAL FIELD OF THE INVENTION

The present invention relates in general to medical packaging systems and, more particularly, to a two-part bag packaging system comprising an administration port and an over-wrap for use with two-part ophthalmic products containing bicarbonate, in which a main package provides moisture and gas-barrier properties.

### BACKGROUND OF THE INVENTION

A number of ophthalmic surgical procedures performed on a patient's eye require irrigation of the surgical site with a sterile irrigation solution. Irrigating solutions for use in surgery, and particularly ophthalmic surgery, are well known; see, for example, commonly assigned U.S. Pat. No. 4,443,432, the contents of which are hereby incorporated by reference in their entirety. In particular, two-part ophthalmic products containing bicarbonate, such as BSS PLUS®, manufactured by Alcon Laboratories, Inc. of Fort Worth, Texas, are well-known and accepted. While the irrigation solutions themselves are well-tested and accepted, problems do exist with current packaging systems for such irrigation solutions.

Typical prior art packaging systems for two-part irrigating solutions comprise two separate glass bottles. One bottle, containing, for example, bicarbonate, is terminally sterilized and the other bottle, containing, for example, glutathione, is sterile filtered. The solution is shipped in two parts and the two parts are reconstituted just prior to use via a syringe or a spike (Monovial). This type of packaging system has several undesirable properties. One is the inherent safety issues associated with transporting and handling glass containers due to the potential for breakage. Further, these prior art packaging systems require a transfer device (e.g., a syringe) to reconstitue the solution, which requires manual manipulation and has the potential of sticking, which can lead to less than complete reconstitution and an increased risk of injury to a patient due to administering unreconstituted solution. Prior art bottle packaging systems also have an increased risk of being non-sterile, since one bottle is sterilized via sterile filtration and aseptically filled. Further still, glass bottles are inherently difficult to ship and dispose of, resulting in an increased environmental impact and increased costs for both.

Therefore, a need exists for a dual-chamber sterilizable packaging system for two-part irrigation or other medical solutions that can reduce or eliminate the problems of safety, reconstitution, sterility and ease of handling associated with prior art sterile packaging systems.

### SUMMARY OF THE INVENTION

The embodiments of the dual-chamber solution packaging system of the present invention substantially meet these needs and others. One embodiment of the dual-chamber solution packaging system of the present invention comprises a plastic laminate gas-impermeable dual-chamber bag, having a first chamber and a second chamber separated by a frangible (releasable) seal, and a plastic laminate over-wrap member enclosing and containing the dual-chamber inner bag. The dual-chamber solution packaging system of this invention can be used to package two-part medicinal products containing bicarbonate, such as ophthalmic irrigation solutions. The first chamber can be filled with and contain a first part of such an irrigation solution, comprising, for example, a buffer such as bicarbonate. The second chamber can contain the second part of such a solution, comprising, for example, glutathione (GSSG), or other anti-oxidant, and dextrose, or other energy source. Both parts may contain other excipients.

The over-wrap member can serve as a dust cover and need not be a moisture or gas barrier, as the dual-chamber inner bag will have sufficient gas barrier properties to minimize the loss of CO₂ from the first part of the solution (e.g., the bicarbonate). All of the components of the dual-chamber solution packaging system can withstand steam sterilization. The dual-chamber bag can be fitted with an administration port, which can be manufactured of, for example, polypropylene (PP), and sealed with a stopper (e.g., butyl rubber stopper) and an aluminum crimp seal. The dual-chamber bag can further comprise fill-ports to fill each chamber. The fill port openings can be sealed after filling the chambers and the fill ports cut from the dual-chamber bag.

The embodiments of the dual-chamber solution packaging system of this invention provide for improved ease of reconstitution of a two-part solution and also provide improved disposability over prior art glass bottle packaging systems, resulting in improved efficacy and patient safety, as well as minimizing the environmental impact from disposal of the used packaging. A preferred irrigation solution that can be packaged in the embodiments of this invention is BSS PLUS®, manufactured by Alcon Laboratories, Inc. of Fort Worth, Tex. BSS PLUS® is a sterile intraocular irrigating solution for use during all intraocular surgical procedures, even those requiring a relatively long intraocular perfusion time (e.g. pars plana vitrectomy, phacoemulsification, extracapsular cataract extraction/lens aspiration, anterior segment reconstruction, etc.). The uses of BSS PLUS® in the packaging system of this invention can be identical to those of the BSS PLUS® product in the prior art two-part glass packaging systems, as compatability with surgical instrumentation permits. The embodiments of this invention can be used to package solutions that do not contain a preservative and that are reconstituted just prior to use in surgery.

The frangible seal between the chambers of the embodiments of this invention can be broken by the end user to mix and reconstitute the two parts of the solution prior to use. In one embodiment, the second part has a fill volume of 150 mL in the upper (second) chamber, while the first part has a fill volume of 350 mL in the lower (first) chamber, which is fitted with the administration port. Other fill volumes are contemplated to be within the scope of this invention and can be used as required for a given application/solution.

### BRIEF DESCRIPTION OF THE FIGURES

A more complete understanding of the present invention and the advantages thereof may be acquired by referring to the following description, taken in conjunction with the accompanying drawings in which like reference numbers indicate like features and wherein:

FIG. 1 is a diagrammatic representation of one embodiment of the dual-chamber solution packaging system 10 of this invention;

FIG. 2 is a diagrammatic representation of one embodiment of the dual-chamber bag 15 of this invention; and

FIG. 3 is a diagrammatic representation of dual-chamber bag 15 of FIG. 2 illustrating exemplary fill ports 100 and administration port 110.

### DETAILED DESCRIPTION OF THE INVENTION

Preferred embodiments of the invention are illustrated in the FIGURES, like numerals being used to refer to like and corresponding parts of the various drawings.

The embodiments of the dual-chamber solution packaging system of this invention provide for improved ease of reconstitution of a two-part solution, improved disposability over prior art glass bottle packaging systems, resulting in improved efficacy and patient safety, as well as reducing the environmental impact from disposal of the used packaging, and for easier shipping of packaged solutions. Although the invention is described herein as a packaging system for BSS PLUS® or other ophthalmic irrigation solution, it should be understood that these solutions are exemplary and the embodiments of this invention can be used to package any two-part solution requiring sterilization and reconstitution (mixing) prior to use.

Returning to the example of BSS PLUS® or other such ophthalmic irrigating solution, such enriched irrigating solutions that can be packaged in the embodiments of the dual-chamber packaging system of this invention are typically composed of two parts, which are reconstituted just prior to use. Part I is a solution containing a naturally occurring buffer, such as bicarbonate, and Part II contains glutathione (GSSG), or other anti-oxidant, and dextrose, or other such energy source. Both Part 1 and Part II may contain other excipients.

The frangible seal between the first and second chambers of the embodiments of this invention can be broken by an end user to allow the contents of the two chambers to mix together to reconstitute the two parts prior to use. As used herein, reconstitution refers to the mixing together, prior to use, of the various parts that will compose a solution to prepare the desired solution for use, and is not meant to imply or suggest a requirement that the separate components were at one time mixed together and then separated, though this can be the case. In one embodiment, Part II has a fill volume of 150 mL in the upper (second) chamber, while the Part I has a fill volume of 350 mL in the lower (first) chamber, which is fitted with the administration port. Other fill volumes are contemplated to be within the scope of this invention and can be used as required for a given application/solution.

The dual-chambered configuration of the embodiments of the present invention can provide several advantages in the use of two-part solutions such as, for example, BSS PLUS®. The frangible seal greatly improves the ease of reconstitution of a packaged two-part solution, which mitigates the risk of injury to a patient by minimizing the likelihood of administering unreconstituted product. Placement of a more physiologically compatible component (e.g., Part I) in the lower chamber of the bag (which is downstream of Part II and hence administered first to a surgical site) further mitigates the risk of injury to the patient by minimizing the potential harm from the inadvertent administration of unreconstituted product. Further, the ability to terminally steam sterilize both parts of the packaged solution provides a greater assurance of sterility, since, for example, as in the case of Part II of a BSS PLUS® solution in prior art packaging systems, one part may have previously had to have been sterilized via sterile filtration and aseptically filled. The risk of injury to the end user (patient) is reduced by replacing, for example, the prior art breakable glass bottles with one flexible plastic bag and by eliminating the need to manipulate a transfer device. Additionally, the administration port of the embodiments of this invention is designed to improve safety during administration set insertion. Finally, empty flexible plastic bags are much easier to dispose of than bulky, breakable glass bottles and will help to minimize the environmental impact due to disposal of used packaging as compared to the prior art.

The gas-impermeable dual-chamber bag of the embodiments of this invention comprises material (film) combinations that have high gas barrier properties to minimize the loss of CO₂ The material for the dual-chamber bag is also preferably flexible, capable of being manufactured with a frangible seal, having good clarity and able to withstand terminal sterilization. Exemplary embodiments of the dual-chamber sterile packaging system of this invention may comprise, but are not limited to, the following:

TABLE 1

| Component | Color | Material |
|---|---|---|
| Dual-chamber bag | Clear | Inner Layer: PP or PP: EVOH co- |
| (e.g., 500 ml) | | extrusion; Additional layers may |
| | | be composed of: Aclar ®^{a}, EVOH, |
| | | PET, SiOx-PET, BON or a |
| | | combination of these. |
| Fill Ports | Natural | Inner layer EVA |
| Administration Port | Natural | Gamma Stable PP |
| Stopper (e.g., 28 mm | Gray | West 4432/50 Gray Butyl Rubber |
| 4432/50) | | |
| Seal (e.g., 28 mm Flip-Off | Natural Seal/Blue Button | Aluminum/Polypropylene |
| seal) | | |
| Over-wrap member | Clear | PET/PP |

^{a}Aclar is a registered trademark of Honeywell International, Inc.
PP = polypropylene
EVOH = ethylene vinyl alcohol co-extrusion
Aclar = polychlorotrifluoroethylene (PCTFE)
PET = polyethylene terephthalate
SiOx-PET = silicon oxide coated polyethylene terephthalate
BON = biaxially oriented nylon
EVA = ethylene vinyl acetate

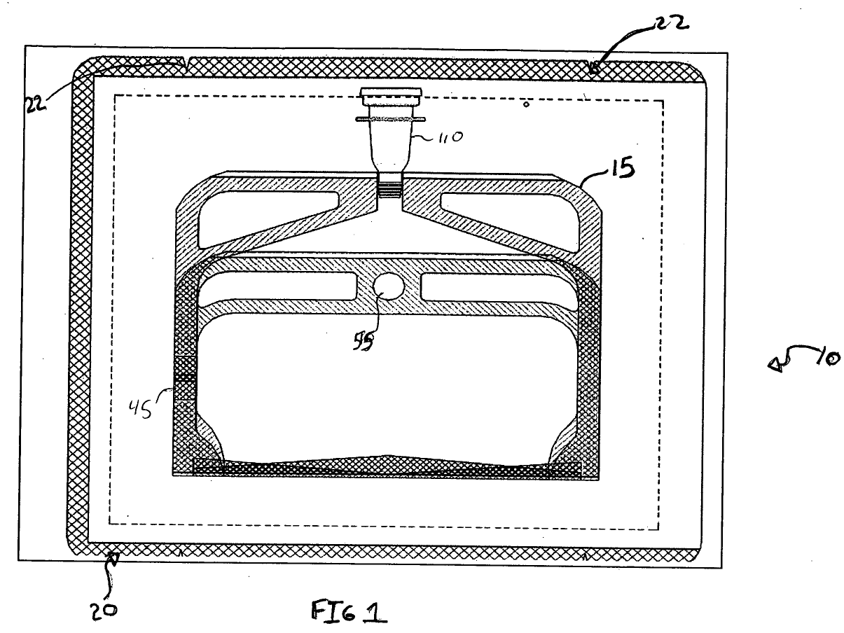

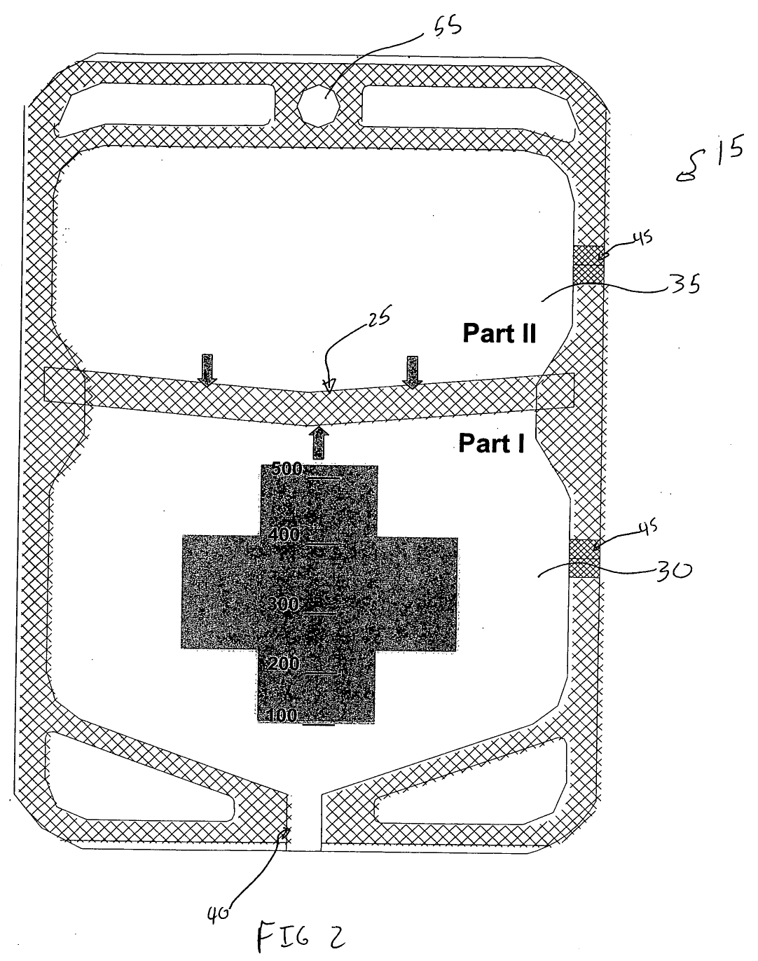

FIG. 1 is a diagrammatic representation of one embodiment of the dual-chamber solution packaging system 10 of this invention. Dual-chamber packaging system 10 can be used to separately contain two different parts of a two-part solution, such as a bicarbonate containing ophthalmic irrigation solution, such that the two parts are not mixed together until a chosen time. This will be explained in greater detail with reference to FIG. 2. Dual-chamber packaging system 10 comprises an inner gas-impermeable dual-chamber bag 15 enclosed in an over-wrap member 20. Gas-impermeable dual-chamber bag 15 can be a plastic laminate dual-chamber bag comprising the materials described above in Table 1, or any other suitable gas-impermeable material as known to those having skill in the art.

Over-wrap member 20 can serve as a dust cover and as a tampering indicator (e.g., if the over-wrap member 20 has been pierced, tampering may have occurred). Over-wrap member 20 need not be a moisture or gas barrier as the dual-chamber bag 15 has sufficient gas barrier properties to minimize the loss of CO₂ from the first part of the solution (e.g., the bicarbonate)). The material of over-wrap member 20 can be polyethylene terephthalate or polypropylene material or other suitable protective material having the functional properties described herein and known to those having skill in the art. Dual-chamber bag 15 of dual-chamber sterile packaging system 10 is contained in the over-wrap member 20 and can be terminally sterilized using steam. Over-wrap member 20 can be sized depending on the application and can be sized, as shown in FIG. 1, to enclose a dual-chamber bag 15 that is folded in half. Alternatively, over-wrap member 20 can be sized to hold a fully extended dual-chamber bag 15 or to any other size that can enclose and contain variously sized and configured dual-chamber bags 15. Over-wrap member 20 is operable to be sealed to contain and protect dual-chamber bag 15 and can be opened, for example, via tear-notches 22 to remove dual-chamber bag 15.

FIG. 2 is a diagrammatic representation of one embodiment of the dual-chamber bag 15 of this invention. Dual-chamber bag 15 comprises a first chamber 30 and a second chamber 35. First chamber 30 and second chamber 35 are intercommunicable compartments isolated from each other by frangible seal 25. A first part (Part I) of a solution to be stored in an embodiment of the packaging system of this invention and mixed together (reconstituted, as will be known to those familiar with the art) prior to use is stored in the first chamber 30 of dual-chamber bag 15. In this embodiment, first chamber 30, containing Part I (e.g., the bicarbonate containing portion of an irrigating solution), will be the lower vertical chamber when the dual-chamber bag 15 is hung for use in a surgical environment in a manner that will be familiar to those having skill in the art. Hanging interface 55, which can comprise an opening through the material of dual-chamber bag 15 having sufficient structural strength to hold the weight of dual-chamber bag 15 without tearing, can be used for hanging dual-chamber bag 15 from, for example, an IV pole.

A second part of the solution (Part II) is contained in the second chamber 35 of the dual-chamber bag 15. Second chamber 35 will be the upper chamber when dual-chamber bag 15 is in use and hence Part II of a solution stored in the dual-chamber bag 15 will be further upstream from the outlet 40 leading to a patient. Frangible seal 25 provides a physical barrier to separate the first chamber 30 and second chamber 35 and can be broken by an end user to allow mixing and reconstitution of the two parts of the two-part solution prior to use. Dual-chamber sterile packaging system 10 can contain, for example, parts I and II of a sterile intraocular irrigating solution comprising a balanced salt solution enriched with bicarbonate, dextrose and glutathione. Dual-chamber bag 15 can be made from a gas-impermeable material, such as described in Table 1 above. Dual-chamber bag 15 is contained in and protected by the over-wrap member 20 that can be gas-permeable, as shown in FIG. 1. Dual-chamber bag 15 can be any arbitrary size as may be required for a given application.

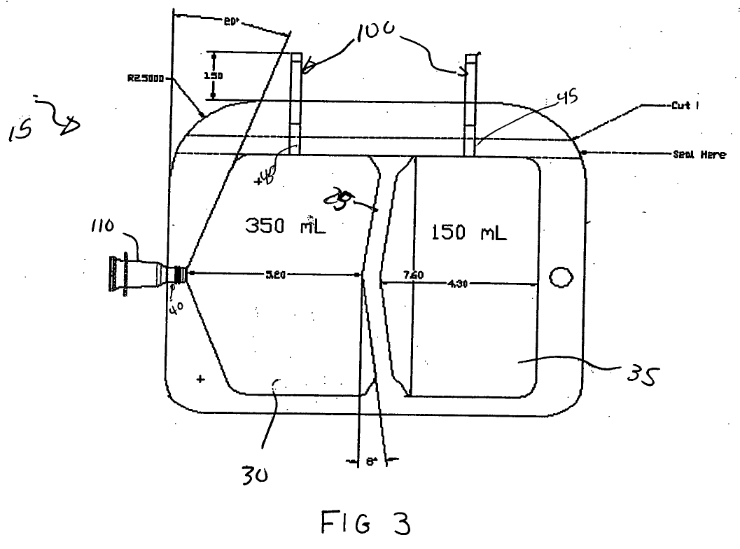

FIG. 3 is a diagrammatic representation of dual-chamber bag 15 of FIG. 2 illustrating exemplary fill ports 100 and administration port 110. Administration port 110 can be a polypropylene (PP) administration port and can be sealed with a butyl rubber stopper and/or an aluminum crimp seal, as will be known to those familiar with the art. Administration port 110 is adapted and operable to attach to dual-chamber bag 15 at outlet 40 and is further operable to seal outlet 40 to contain Part I of a solution within chamber 30 (and consequently all parts of the solution within the dual-chamber bag 15 when the bag is intact) in cooperation with the butyl stopper and/or the aluminum crimp seal (not shown). Administration port 110 will hang below the first and second chambers when dual-chamber bag 15 is hung during use. Administration port 110 is operable to receive an administration set operable to couple dual-chamber bag 15 to, for example, the fluidic system of an ophthalmic surgical system, as will be known to those having skill in the art. Administration port 100 is Fill ports 100 are used to fill chambers 30 and 35 with the respective parts of a two-part solution and the openings 45 into the first and second chambers 30 and 35 from fill ports 100 can be sealed after filling the chambers and the fill ports 100 cut from dual-chamber bag 15. The openings 45 into chambers 30 and 35 can be, for example, thermally sealed or sealed by other means as will be known to those having skill in the art.

Although the embodiments of the dual-chamber solution packaging system of the present invention have been described herein as comprising a dual-chamber bag 15, it should be understood that other embodiments are contemplated to be within the scope of this invention that can instead comprise a plurality of chambers, such as first and second chambers 30 and 35, for containing the different parts of a solution having a plurality of different parts that require mixing just prior to use. Further, the various embodiments of the present invention can be manufactured by heat sealing to bond the various components or by any other manufacturing procedures for making plastic or plastic laminate packaging as will be known to those familiar with the art.

The various embodiments of the present invention, in a preferred embodiment, comprise a dual-chamber bag 15 material having a high enough gas barrier property to minimize CO2 loss on autoclaving and during storage, have a clarity sufficient to allow for leak and particulate inspection and volume monitoring during use and have an administration port 110 compatible with existing infusion/irrigation administration sets, such as a spike. Embodiments should preferably withstand steam sterilization and be capable of printing on both the dual-chamber inner bag 15 and the over-wrap member 20.

As used herein, “gas-impermeable” refers to those characteristics of a material for use in a packaging system as described herein for minimizing the loss of gas generated by portions of a stored solution, as will be known to those familiar with the art, and is not meant to necessarily mean complete and/or inherent gas-impermeability. In particular, gas-impermeability may be achieved by use of a sufficiently thick member of a material that, at a smaller thickness, might not be considered gas-impermeable.

The embodiments of the dual-chamber solution packaging system of this invention can achieve long-term stabilization of a medicinal solution, such as, for example, an irrigation solution having a naturally occurring buffer, such as bicarbonate, and containing glutathione (GSSG), or other anti-oxidant, and dextrose, or other energy source.

While the present invention has been described with reference to particular embodiments, it should be understood that the embodiments are illustrative and that the scope of the invention is not limited to these embodiments. Many variations, modifications, additions and improvements to the embodiments described above are possible. It is contemplated that these variations, modifications, additions and improvements fall within the scope of the invention as detailed in the following claims.

What is claimed is:

1. A solution packaging system, comprising:
a dual-chamber gas-impermeable bag having a first chamber and a second chamber, wherein the chambers are operable to enclose contents and are separated by a releasable seal; and
an over-wrap member operable to enclose and contain the dual-chamber gas-impermeable bag.

2. The solution packaging system of claim 1, wherein the solution is a two-part solution having a first part and a second part to be mixed together prior to use, and wherein the first part is enclosed in the first chamber and the second part is enclosed in the second chamber.

3. The solution packaging system of claim 2, wherein the solution is a two-part ophthalmic irrigating solution, and wherein the first part comprises a bicarbonate buffer and the second part comprises glutathione (GSSG) and dextrose.

4. The solution packaging system of claim 2, wherein the releasable seal is operable to be broken by a user to allow mixing of the first part and the second part to reconstitute the solution.

5. The solution packaging system of claim 1, wherein the releasable seal is a frangible seal.

6. The solution packaging system of claim 1, wherein the dual-chamber gas-impermeable bag and the over-wrap member are composed of plastic laminate.

7. The solution packaging system of claim 1, wherein the dual-chamber gas-impermeable bag and the over-wrap member can be steam-sterilized.

8. The solution packaging system of claim 1, wherein the dual-chamber gas-impermeable bag further comprises an administration port operable to release the dual-chamber bag contents, and a fill port for each of the first and second chambers.

9. The solution packaging system of claim 8, wherein the administration port is operable to receive an administration set operable to couple the dual-chamber gas-impermeable bag to a fluidic system of an ophthalmic surgical system.

10. The solution packaging system of claim 8, wherein the administration port is in fluid communication with only one chamber when the releasable seal is intact.

11. The solution packaging system of claim 8, wherein the administration port comprises a stopper and a crimp seal operable to seal the administration port.

12. The solution packaging system of claim 8, wherein the fill ports are adapted to be cut from the dual-chamber gas-impermeable bag following a filling of their respective chambers, and wherein openings on the dual-chamber gas-impermeable bag corresponding to the fill ports can be sealed to contain the contents.

13. The solution packaging system of claim 1, wherein the dual-chamber gas-impermeable bag further comprises a hanging interface for hanging the dual-chamber bag during use.

14. The solution packaging system of claim 13, wherein the chamber that is the lower chamber when the dual-chamber bag is hung from the hanging interface during use contains a more physiologically compatible component of the two chambers, and wherein the dual-chamber gas-impermeable bag further comprises an administration port operable to release the dual-chamber bag contents, wherein the administration port is in fluid communication with only the lower chamber when the releasable seal is intact.

15. The solution packaging system of claim 14, wherein the contents of the dual-chamber gas-impermeable bag flow out of the administration port during use, wherein the administration port hangs lower than either of the first and second chambers.

16. A solution packaging system, comprising:
a gas-impermeable bag; and
an over-wrap member operable to enclose and contain the gas-impermeable bag.

17. The solution packaging system of claim 16, wherein the gas-impermeable bag is a dual-chamber gas-impermeable bag having a first chamber and a second chamber, wherein the chambers are operable to enclose contents and are separated by a releasable seal.

18. The solution packaging system of claim 17, wherein the solution is a two-part solution having a first part and a second part to be mixed together prior to use, and wherein the first part is enclosed in the first chamber and the second part is enclosed in the second chamber.

19. The solution packaging system of claim 18, wherein the solution is a two-part ophthalmic irrigating solution, and wherein the first part comprises a bicarbonate buffer and the second part comprises glutathione (GSSG) and dextrose.

20. The solution packaging system of claim 18, wherein the releasable seal is operable to be broken by a user to allow mixing of the first part and the second part to reconstitute the solution.

21. The solution packaging system of claim 17, wherein the releasable seal is a frangible seal.

22. The solution packaging system of claim 16, wherein the gas-impermeable bag and the over-wrap member are composed of plastic laminate.

23. The solution packaging system of claim 16, wherein the gas-impermeable bag and the over-wrap member can be steam-sterilized.

24. The solution packaging system of claim 16, wherein the gas-impermeable bag further comprises an administration port operable to release the gas-impermeable bag contents.

25. The solution packaging system of claim 24, wherein the administration port is operable to receive an administration set operable to couple the gas-impermeable bag to a fluidic system of an ophthalmic surgical system.

26. The solution packaging system of claim 16, wherein the gas-impermeable bag further comprises a hanging interface for hanging the gas-impermeable bag during use.

27. The solution packaging system of claim 16, wherein the gas-impermeable bag has a plurality of chambers, wherein the chambers are operable to enclose contents and wherein each chamber is separated from the others by one or more releasable seals.

28. A solution packaging system, comprising:
a dual-chamber gas-impermeable bag, comprising:
a first chamber;
a second chamber, wherein the first and second chambers are intercommunicable and operable to enclose contents and are separated by a releasable seal;
an administration port operable to release the dual-chamber bag contents;
a fill port for each of the first and second chambers; and
a hanging interface for hanging the dual-chamber bag during use; and
an over-wrap member operable to enclose and contain the dual-chamber gas-impermeable bag.

29. The solution packaging system of claim 28, wherein the solution is a two-part solution having a first part and a second part to be mixed together prior to use, and wherein the first part is enclosed in the first chamber and the second part is enclosed in the second chamber.

30. The solution packaging system of claim 29, wherein the solution is a two-part ophthalmic irrigating solution, and wherein the first part comprises a bicarbonate buffer and the second part comprises glutathione (GSSG) and dextrose.

31. The solution packaging system of claim 29, wherein the releasable seal is operable to be broken by a user to allow mixing of the first part and the second part to reconstitute the solution.

32. The solution packaging system of claim 28, wherein the releasable seal is a frangible seal.

33. The solution packaging system of claim 28, wherein the dual-chamber gas-impermeable bag and the over-wrap member can be steam-sterilized.

34. The solution packaging system of claim 28, wherein the administration port is operable to receive an administration set operable to couple the dual-chamber gas-impermeable bag to a fluidic system of an ophthalmic surgical system.

35. The solution packaging system of claim 28, wherein the administration port is in fluid communication with only one chamber when all the releasable seals are intact.

36. The solution packaging system of claim 28, wherein the administration port comprises a stopper and a crimp seal operable to seal the administration port.
